(19) United States
(12) Patent Application Publication
(10) Pub. No.: US 2012/0044341 A1
(43) Pub. Date: Feb. 23, 2012

(54) OPTOFLUIDIC MICROSCOPE SYSTEM-ON-CHIP

(76) Inventors: Curtis W. Stith, Santa Cruz, CA (US); Kenneth Edward Salsman, Pleasanton, CA (US); Dmitry Bakin, San Jose, CA (US); Ulrich Boettiger, Garden City, ID (US)

(21) Appl. No.: 13/205,340

(22) Filed: Aug. 8, 2011

Related U.S. Application Data
(60) Provisional application No. 61/375,227, filed on Aug. 19, 2010.

(51) Int. Cl. H01L 27/146; H04N 5/228; H04N 7/18; H04N 5/335

(52) U.S. Cl. 348/79; 250/208.1; 348/294; 348/222.1; 348/E05.091; 348/E05.031; 348/E07.085

(57) ABSTRACT

An integrated circuit may contain image sensor pixels. Channels containing a fluid with samples such as cells may be formed on top of the image sensor. Control circuitry may be formed on the integrated circuit. The image sensor pixels may form light sensors and imagers. Portions of the channel may have multiple chambers such as fluorescence detection chambers. Gating structures and other fluid control structures may control the flow of fluid through the channels and chambers. Portions of the channel may be used to form chambers. The chambers may each be provided with one or more light sensors, light sources, and color filters to alter the color of illumination form a light source, one or more reactants such as dyes, antigens, and antibodies, and heaters. The control circuitry may be configured to control the imagers, the gating structures, the fluid control structures, the light source, the heaters, etc.

This application claims the benefit of provisional patent application No. 61/375,227, filed Aug. 19, 2010, which is hereby incorporated by reference herein in its entirety.

### BACKGROUND

This relates generally to electronic devices and more particularly to electronic devices having optofluidic microscopes.

Optofluidic microscopes have been developed that can be used to generate images of cells and other biological specimens. The cells are suspended in a fluid. The fluid flows over a set of image sensor pixels in a channel. The image sensor pixels may be associated with an image sensor pixel array that is masked using a metal layer with a pattern of small holes. In a typical arrangement, the holes and corresponding image sensor pixels are arranged in a diagonal line that crosses the channel. As cells flow through the channel, image data from the pixels may be acquired and processed to form high-resolution images of the cells.

In a conventional electronic device containing an optofluidic microscope, operation of microscope components is controlled using external circuitry. Controlling optofluidic microscopes with external circuitry may increase the volume required in an electronic device housing containing an optofluidic microscope and external circuitry and may increase the cost of production of the device.

It would be therefore be desirable to provide optofluidic microscopes or other electronic devices with improved control systems.

### BRIEF DESCRIPTION OF THE DRAWINGS

FIG. 1 is a diagram of an illustrative electronic device having an optofluidic microscope system-on-chip in accordance with an embodiment of the present invention.

FIG. 2 is a diagram of an illustrative optofluidic microscope system-on-chip in accordance with an embodiment of the present invention.

FIG. 3 is a diagram of an illustrative optofluidic microscope component of an optofluidic microscope system-on-chip in accordance with an embodiment of the present invention.

FIG. 4 is a top view of an illustrative fluid channel that contains a gate structure for controlling the flow of fluid in accordance with an embodiment of the present invention.

FIG. 5 is a cross-sectional side view of a portion of an image sensor pixel array of the type that may be used in a fluid channel in an electronic device of the type shown in FIG. 1 in accordance with an embodiment of the present invention.

FIG. 6 is a cross-sectional diagram showing how image sensor pixels may be used to form a light sensor associated with a chamber in accordance with an embodiment of the present invention.

FIG. 7 is a cross-sectional end view of an illustrative chamber having an entrance port for receiving a sample in accordance with an embodiment of the present invention.

FIG. 8 is a cross-sectional end view of an illustrative chamber having a heater and a flow control electrode in accordance with an embodiment of the present invention.

FIG. 9 is a cross-sectional end view of an illustrative chamber having a light source and a reactant in accordance with an embodiment of the present invention.

FIG. 10 is a top view of an illustrative system having multiple channels with multiple imagers in accordance with an embodiment of the present invention.

FIG. 11 is a graph of illustrative control signals that may be applied to the gate structures in respective channels to ensure that a sample is exposed to different reactants for appropriate amounts of time before being imaged by respective imagers in accordance with an embodiment of the present invention.

FIG. 12 is a perspective view of illustrative system environment in which an electronic device of the type shown in FIG. 1 may be used to gather image data of cells and other biological specimens in accordance with an embodiment of the present invention.

FIG. 13 is a flow chart of illustrative steps involved in using an electronic device having an optofluidic microscope system-on-chip in accordance with an embodiment of the present invention.

### DETAILED DESCRIPTION

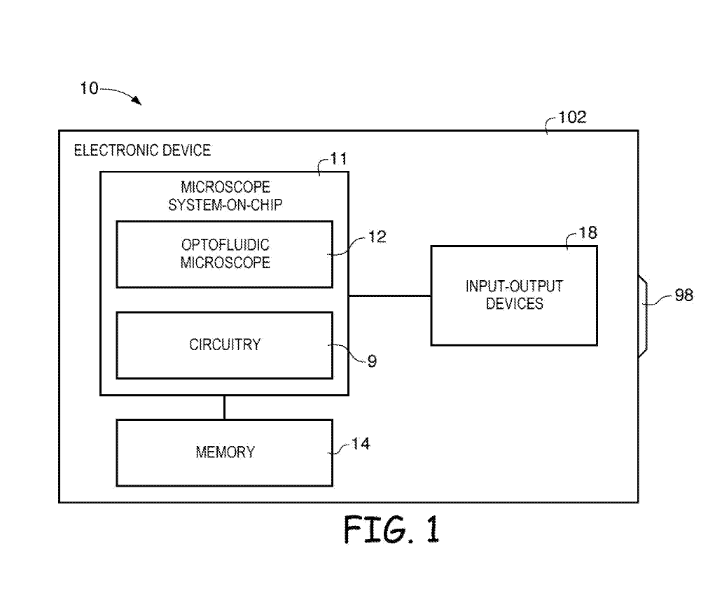

An electronic device of the type that may be used to image and otherwise evaluate cells and other samples such as biological specimens is shown in FIG. 1. As shown in FIG. 1, electronic device 10 may include optofluidic microscope system-on-chip (SOC) 11. Optofluidic microscope SOC 11 may include an optofluidic microscope (OFM) 12 for imaging and evaluating samples. Optofluidic microscope SOC 11 (sometimes referred to herein as microscope SOC, OFM-SOC, etc.) may include processing and control circuitry such as circuitry 9 for operations such as operating optofluidic microscope 12. Circuitry 9 associated with microscope SOC 11 may include circuitry formed on a common integrated circuit die together with the optofluidic microscope (sometimes referred to as a system-on-chip or SOC arrangement). If desired, microscope SOC 11 may include additional circuitry formed on a separate integrated circuit die. Electronic device 10 may, if desired, include storage such as memory 14. Memory 14 may include volatile memory (e.g., static or dynamic random-access memory), non-volatile memory (e.g., flash memory), etc. Memory 14 may be configured to store image data, processed image data, spectral data, florescence data, sample identifying data, analysis results, etc. resulting from operation of optofluidic microscope SOC 11. Electronic device 10 may provide a user with the ability to interact electronic device 10. User interactions may include inputting identifying information (e.g., information identifying a sample, a sample donor, a geographic location, etc.) and obtaining output information (e.g., reading the result of an analysis performed by the optofluidic microscope), etc. To implement these interactions, electronic device 10 may have input-output devices 18 such as keypads, virtual keypads, buttons, displays, or other suitable input-output components. Input-output devices 18 may be associated with one or more output ports such as output port 98 mounted in a housing such as housing 102 of device 10.

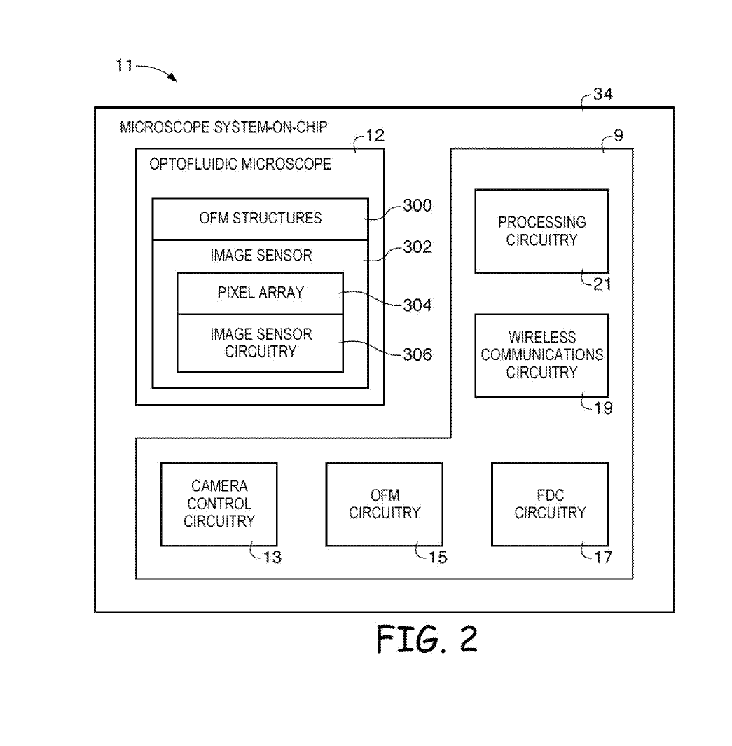

An illustrative configuration that may be used for optofluidic microscope SOC 11 is shown in FIG. 2. As shown in FIG. 2, microscope SOC 11 may include an optofluidic microscope (OFM) 12, and circuitry 9 that includes control circuitry such as camera control circuitry 13, OFM control circuitry 15, fluorescence detection chamber (FDC) control circuitry 17, wireless communications circuitry 19 and/or general purpose processing circuitry such as processing circuitry 21. In the system-on-chip or SOC arrangement of microscope SOC 11, OFM 12, camera control circuitry 13, microscope control circuitry (i.e., OFM control circuitry) 15, channel control circuitry (i.e., FDC control circuitry) 17, wireless communications circuitry 19 and processing circuitry 21 are implemented on common integrated circuit die 34 (sometimes referred to herein as semiconductor substrate 34, integrated circuit 34, integrated circuit substrate 34, or substrate 34). The use of a single integrated circuit such as integrated circuit 34 to implement OFM-SOC 11 can help to minimize costs and reduce the size of electronic device 10 of FIG. 1.

OFM 12 may include an image sensor (or imager) such as image sensor 302 for imaging samples within OFM 12. Camera control circuitry 13 of FIG. 2 may be used to control imaging functions for OFM 12. OFM 12 may include an array of image pixels such as pixel array 304 and image sensor circuitry such as image sensor circuitry 306. Image sensor circuitry may row control circuitry, column readout circuitry, analog-to-digital conversion circuitry or other circuitry associated with the capture of raw data using image pixels of imager 302.

OFM 12 may include optofluidic microscope (OFM) structures such as one more channels through which fluid may flow during operation of OFM 12. Camera control circuitry 13 may be used to direct imager 302 of OFM 12 to image the fluid as it flows through one of the channels of OFM 12. Camera control circuitry 13 may be configured to control exposure time of an imager associated with OFM-SOC 11, to perform image correction operations such as white balance and color correction operations, or to otherwise operate imaging functions of OFM-SOC 11. OFM circuitry 15 may be used to control the flow of fluids in channels of OFM 12. OFM structures 300 may include fluid control structures (e.g., gates, electrodes, etc.) for controlling the flow of fluids through the channels of OFM 12. OFM circuitry 15 may be used to operate fluid control structures during analysis of fluid samples. OFM 12 may include one or more florescence detection chambers (FDCs) for collecting and analyzing fluid samples within OFM 12. FDC control circuitry 17 may be used to operation FDC components such as heaters, electrodes, light sources, etc. that may induce florescence of fluid or other samples within an FDC.

OFM-SOC 11 may also include wireless communications circuitry such as wireless communications circuitry 19. Wireless communications circuitry 19 may be used to transmit wireless data to remote equipment such as a computer, a handheld electronic device, a cellular telephone, a network router, a network antenna, etc. For example, wireless communications circuitry 19 may be configured to transmit or receive data at WiFi® frequencies (e.g., 2.4 GHz and 5 GHz), Bluetooth® frequencies (e.g., 2.4 GHz), cellular telephone frequencies (e.g., 850 MHz, 900 MHz, 1800 MHz, 1900 MHz, and 2100 MHz), or other frequencies. Wireless data transmitted using wireless communications circuitry 19 may include identifying data of a particular OFM-SOC, identifying data of a sample, geographic location data identifying the location of the OFM-SOC, analysis data resulting from analysis of a sample within an OFM-SOC such as OFM-SOC 11, imaging data obtained using OFM-SOC 11, etc.

OFM-SOC 11 may further include general purpose processing circuitry such as processing circuitry 21 of FIG. 2. Processing circuitry 21 of OFM-SOC 11 may be configured to operate a display associated with electronic device 10 (see FIG. 1), perform analysis tasks on data obtained using OFM control circuitry 15, camera control circuitry 13, and FDC control circuitry 17. Processing circuitry 21 may be used for additional processing or compression of images captured using OFM 12, may be used for spectral analysis of imaging data obtained using OFM 12, etc. Processing circuitry 21 may be used for temperature control operations. For example, processing circuitry 21 may include temperature control elements such as one or more resistive elements that increase in temperature when a current is applied or other temperature control elements for cooling some or all of OFM 12. Heating of resistive elements of processing circuitry 21 may help heat microscope SOC 11, OFM 12, or individual portions of OFM 12.

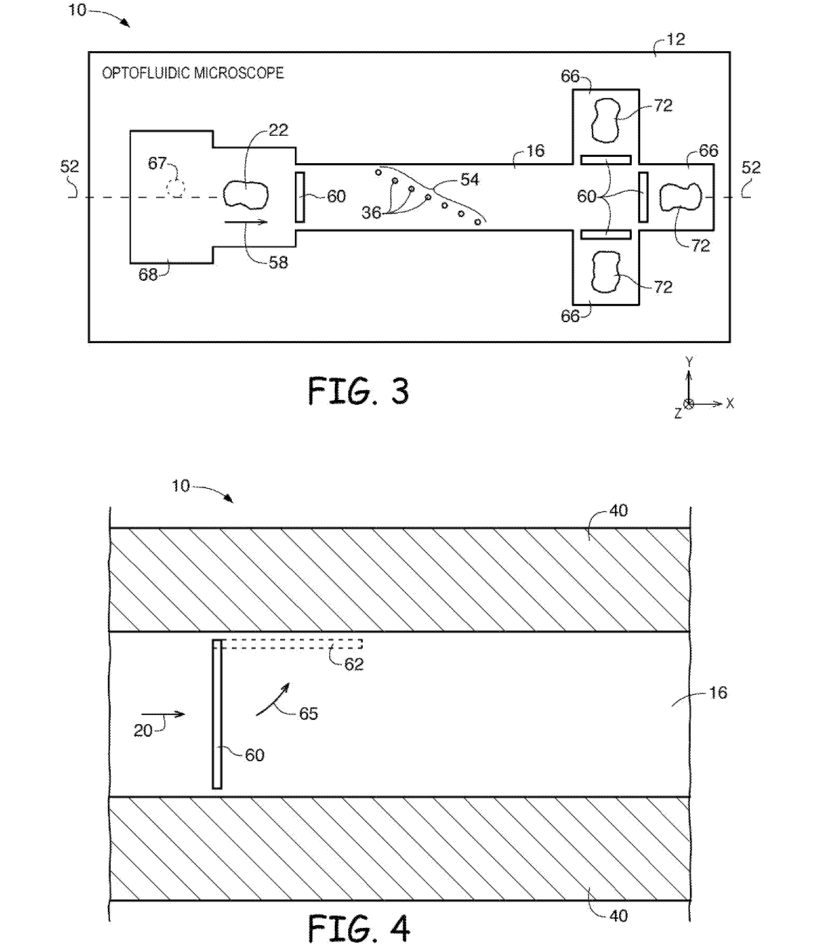

As shown in FIG. 3, OFM 12 of device 10 may include pixels 36 in one or more channels such as channel 16. Pixels 36 of channel 16 may form a portion of pixel array 304 of image sensor 302 of FIG. 2 and may be arranged to form imager 54 in channel 16. Pixels 36 may be arranged in a diagonal line that extends across the width of channel 16 or may be arranged in other suitable patterns. The use of a diagonal set of image acquisition pixels 36 in channel 16 may help improve resolution (i.e., lateral resolution in dimension y perpendicular to longitudinal axis 52) by increasing the number of pixels 36 per unit length in dimension x. The image acquisition pixels 36 in channel 16 (i.e., the imager sensor pixels) are sometimes referred to as forming an image acquisition region, image sensor, or imager.

OFM 12 may include a light source configured to be adjusted to produce one or more different colors of light during image acquisition operations. Channels 16 in OFM 12 of device 10 (see FIG. 1) may be provided with one or more imagers 54. The different colors of light may be used in gathering image data in different color channels. If desired, a different respective light color may be used in illuminating a sample such as sample 22 as sample 22 passes each respective imager within a set of multiple imagers 54 in a given channel by moving in direction 58 with a fluid in the channel.

In some situations, it may be desirable to mix sample 22 with a reactant such as reactants 72. Examples of reactants that may be introduced into channel 16 with sample such as sample 22 include diluents (e.g., fluids such as ionic fluids), dyes (e.g., fluorescent dyes) or other chemical compounds, biological agents such as antigens, antibodies (e.g., antibodies with dye), reagents, phosphors, electrolytes, analyte-specific antibodies, etc.

With one suitable arrangement, one or more reactants may be introduced within a portion of channel 16. The portion of channel 16 that receives the reactant may be, for example, a portion of channel 16 that has been widened or a portion of channel 16 that has the same width as the rest of the channel. Portions of channel 16 (whether widened or having other shapes) that receive reactant or that may be used to introduce sample material into channel 16 are sometimes referred to herein as chambers (or reservoirs, evaluation chambers, fluorescence detection chambers, etc.) 66. In the example of FIG. 3, channel 16 has three associated evaluation chambers 66 containing reactant 72. Each chamber 66 may contain a different reactant or a reactant in a different concentration from the reactant in another chamber 66. OFM 12 of FIG. 3 having a single channel 16 having three associated chambers 66 is merely illustrative. OFM 12 may contain more than one channel 16. Each channel 16 may contain one chamber 66, no chambers 66, two chambers 66, three chambers 66 or, if desired, more than three chambers 66.

Channels 16 in OFM 12 may be provided with fluid control components such as electrodes or gating structures. As shown in FIG. 3, channels 16 in OFM 12 may be provided with configurable gate structures (gating structures) such as gate structures 60 used to selectively block the flow of a fluid containing sample 22. In the example of FIG. 3, OFM 12 contains a gate structure 60 that controls the flow of a fluid containing sample 22 from entrance chamber 68 into channel 16. Entrance chamber 68 may contain an entrance port 67 through which fluid samples may be introduced into OFM 12. OFM control circuitry 15 (see FIG. 2) may be configured to operate a gate structure such as gate structure 60 that is interposed between entrance chamber 68 and channel 16 to allow sample 22 to flow into channel 16. Imager 54 may be used to capture image data of sample 22 as sample 22 flows past image sensor pixels 36 in channel 16.

As shown in FIG. 3, OFM 12 may be provided with additional gate structures 60 adjacent to each evaluation chamber 66. Gate structures 60 associated with chambers 66 may be selectively operated using OFM control circuitry 15 to allow sample 22 to flow into a selected chamber 66. Gate structures 60 may be opened using OFM control circuitry 15 in such a way that sample 22 first enters one chamber 66 having a first reactant 72 and subsequently enters a different chamber 66 having a different reactant 72.

FIG. 4 shows how gate structures such as gate structure 60 may be operated by OFM control circuitry 15 to control the flow of samples such as sample 22 (FIG. 3) in a fluid 20 through channels 16 of OFM 12. As shown in FIG. 4, gate structure 60 may have open and closed positions. In the example of FIG. 4, gate structure 60 in its closed position in which the flow of fluid 20 is blocked. When moved in direction 65 to open position 62, or when otherwise opened, gate structure 60 permits fluid 20 to flow through channel 16. Gate structures such as gate structure 60 may, for example, be formed from MEMs structures, electrode-based structures, or other structures that can selectively permit fluid to flow or block fluid from flowing. Electrodes or other fluid control mechanisms (e.g., MEMs structures, external pumps, etc.) associated with optofluidic microscope 12 may be used to cause the sample fluid to flow through channel 16. Gate structures such as gate structure 60 may be used to selectively block the flow of the sample. For example, gate structure 60 may be placed in a closed position to momentarily prevent fluid from flowing and thereby ensure that the fluid remains in contact with a reactant for an amount of time that is appropriate for that reactant to interact with the sample. Once the appropriate amount of time has elapsed, control circuitry such as OFM circuitry 15 or FDC circuitry 17 (see FIG. 2) may open gate structure 60 to allow the fluid sample to proceed past one or more imagers 54 or to flow into one or more chambers such as chambers 66 of FIG. 3.

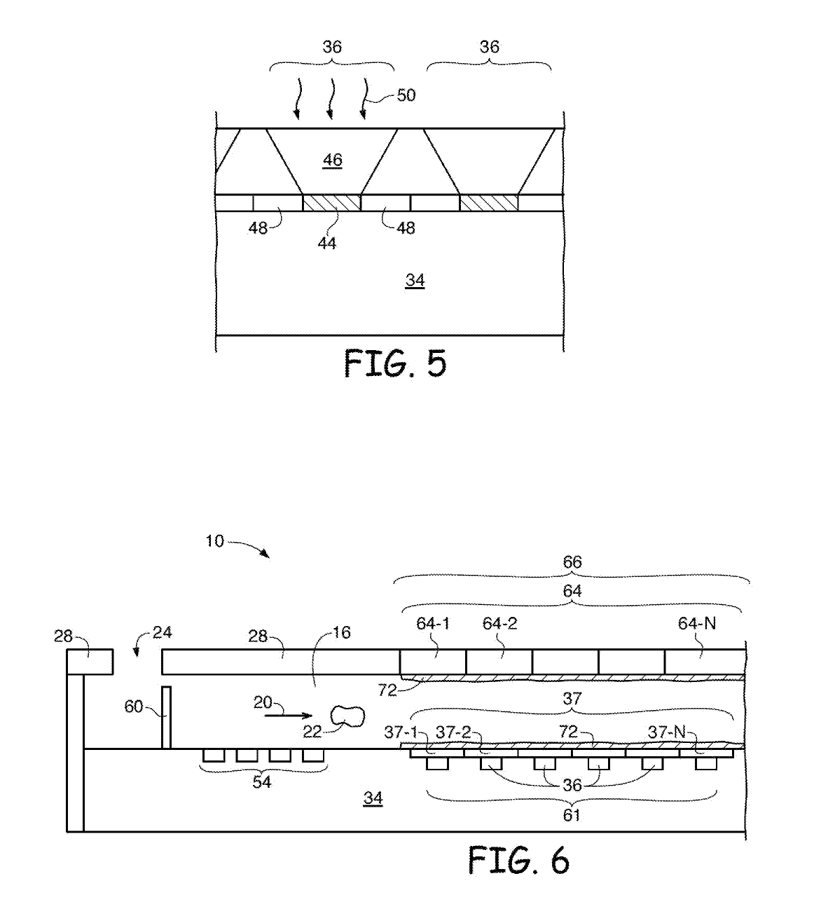

A cross-sectional side view of an illustrative image sensor pixel 36 is shown in FIG. 5. As shown in FIG. 5, image sensor pixels 36 on integrated circuit 34 may each include a corresponding photosensitive element such as photodiode 44. Complementary metal-oxide-semiconductor (CMOS) technology or other image sensor integrated circuit technologies may be used in forming image sensor pixels 36 and integrated circuit 34. Light guides such as light guide 46 may be used to concentrate incoming image light 50 into respective photodiodes 44. Photodiodes 44 may each convert incoming light into corresponding electrical charge. Image sensor circuitry 48, may be used to convert the charge from photodiodes 44 into analog and/or digital image data. In a typical arrangement, data is acquired in frames. Camera control circuitry 13 may convert raw digital data captured using image sensor circuitry 48 from one or more acquired image data frames into images of samples 22. Camera control circuitry 13 may perform other high level processing on images of samples 22 (e.g., white balance corrections, color corrections, etc.).

A cross-sectional side view of an illustrative optofluidic microscope having a chamber that has been provided with reactant is shown in FIG. 6. In electronic device 10 of FIG. 4, a fluid sample can be introduced into channel 16 on integrated circuit substrate 34 through entrance port 24 in glass layer 28. The fluid and associated particles within the fluid such as sample 22 may flow through channel 16 as illustrated by fluid flow arrow 20. Imager 54 may be used to gather images of sample 22 as sample 22 passes over imager 54.

Part of channel 16 may be used to form chamber 66. Chamber 66 may be provided with reactant such as reactant 72 and/or components for evaluating samples such as cell 22. As shown in FIG. 6, for example, reactant 72 such as a fluorescent dye or other reactant may be used to cover the lower surface and/or upper surface of chamber 66. Chamber 66 may therefore be a fluorescence detection chamber (FDC) configured to detect fluorescence by sample 22 using FDC control circuitry 17 on integrated circuit 34. The lower surface of chamber 66 (i.e., the lower surface of channel 16) may have a pattern of image sensor pixels 36 that form one or more light sensors (e.g., one or more light meters) such as light sensor 61. Light sensor 61 may be formed from a portion of pixel array 304 of FIG. 2. The image pixels that make up light sensor 61 may be used collectively (i.e., in a binned fashion) to improve noise performance and/or may be used individually (or in small groups associated with respective light sensors) to gather location-dependent light readings. FDC control circuitry 17 or camera control circuitry 13 of FIG. 2 may be configured to selectively use pixels 36 collectively or individually. Reactant 72 may be formed on or near the image sensor pixels 36 in chamber 66 and/or on the upper surface of channel 16 (as examples). When fluid and samples 22 reach chamber 66, reactant 72 may react with the fluid and/or cells. For example, dye in layers 72 may dye the cells.

In the illustrative configuration of FIG. 6, upper portion 64 of chamber 16 has been provided with elements 64-1, 64-2, . . . 64-N. Elements 64-1, 64-2, . . . 64-N may be transparent colored filter elements that are arranged in a tiled fashion over the upper surface of chamber 66. Each filter element may be used to filter light entering and/or exiting chamber 66. For example, each filter element may be used to filter a white light illumination source, thereby illuminating the interior of chamber 66 with various different types of colored light. The sample within chamber 66 (e.g., the fluid containing dyed cells or other sample particles) may respond differently to different colors of light. For example, the sample may fluoresce in response to illumination with one color of light but not in response to another. The use of different colors of light to illuminate different portions of the sample with different wavelengths of interest can therefore be useful in analyzing the sample. Filter elements 37-1, 37-2, . . . 37-N may also be used to filter light emissions from within chamber 66. Lower portion 37 of chamber 66 has been provided with elements 37-1, 37-2, . . . 37-N. Elements 37-1, 37-2, . . . 37-N may be transparent colored filter elements that are arranged in a tiled fashion over the upper surface of chamber 66. Each filter element may be used to filter light entering light sensor 61. For example, each filter element may be used to filter a white light illumination source, thereby illuminating the portions of light sensor 61 with various different types of colored light. The collection of different colors of light using light sensor 61 can therefore be useful in analyzing the sample. Reactant 72 may be provided in a uniform coating over a sidewall, over a lower chamber surface, over an upper chamber surface, or in other suitable chamber regions. If desired, reactant 72 may be patterned. For example, some regions of a chamber may be coated with reactant and other regions of the chamber may be left uncoated. Different reactants may be provided in different regions (e.g., in a tiled pattern on the lower or upper surface of the chamber, etc.). Any suitable number of different reactants may be used within one chamber (e.g., one, two, three, four, more than four, etc.). Channel 16 may be provided with gate structures such as gate structure 60 for controlling the flow of fluid 20 into chamber 66.

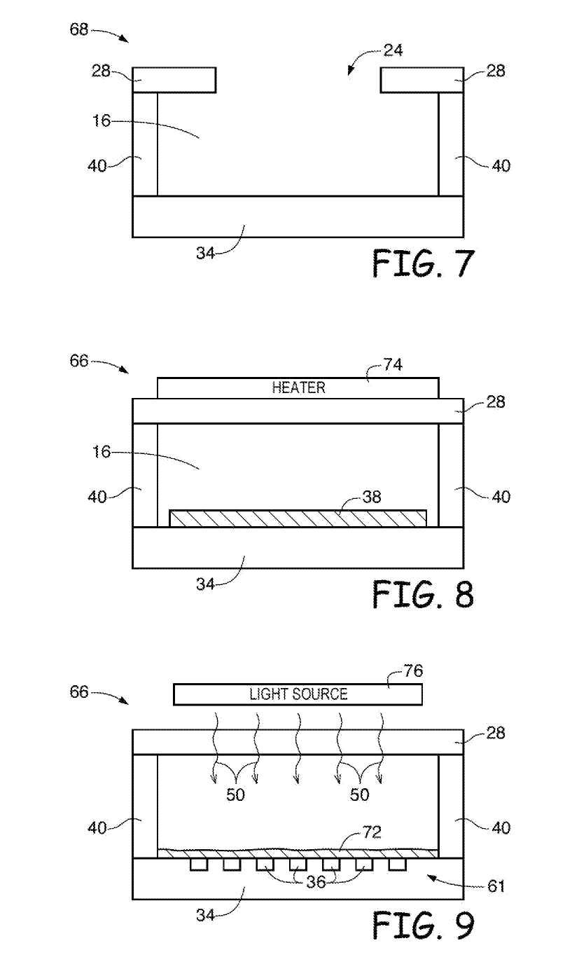

FIGS. 7, 8, and 9 are cross-sectional end views of illustrative types of chambers that may be used in implementing chambers in OFM 12 of OFM-SOC 11 of device 10. As shown in FIG. 7, entrance chamber 68 may contain an entrance port. Samples may be introduced into chamber 68 for distribution to an array of channels 16. Structures such as standoffs 40 (e.g., polymer standoffs) may be used to elevate the lower surface of glass layer 28 from the upper surface of integrated circuit 34. This forms one or more channels 16. Channels 16 may have lateral dimensions (dimensions parallel to dimensions x and z in the example of FIG. 3) of a millimeter or less (as an example). The length of each channel (the dimension of channel 16 along dimension y in the example of FIG. 3) may be 1-10 mm, less than 10 mm, more than 10 mm, or other suitable length. Standoff structures 40 may be patterned to form sidewalls for channels such as channel 16.

FIG. 8 shows how evaluation chamber 66 may be provided with a temperature control element such as heater 74. Heater 74 may be, for example, a resistive heater that is controlled by FDC control circuitry 17 or processing circuitry 21 (FIG. 2). During sample evaluation operations, heater 74 may be turned on and off to cycle the temperature in the interior of the chamber. Voltages may be applied to chambers such as chamber 66 of FIG. 8 using electrodes such as electrode 38. By controlling the voltages on electrodes 38 in chambers 66 and/or other channel structures in OFM 12 using FDC control circuitry 17, the flow of sample fluids such as ionic fluids may be controlled.

As shown in the example of FIG. 9, chamber 66 may be provided with a light source such as light source 76 that produces light 78 of one or more different colors (using optional color filters in light source 76 and/or light filters integrated into the upper surface of chamber 66 in a pattern of the type shown in FIG. 9). Reactant 72 may be provided on any of the exposed surfaces of chamber 66. In the FIG. 8 example, reactant 72 has been provided on a lower chamber surface (as an example). Image sensor pixels 36 may be used to form one or more image sensors 61. Image sensor pixels 36 of image sensors 61 may be configured to receive light of various colors (using optional color filters over image sensor pixels 36 or integrated into the lower surface of chamber 66).

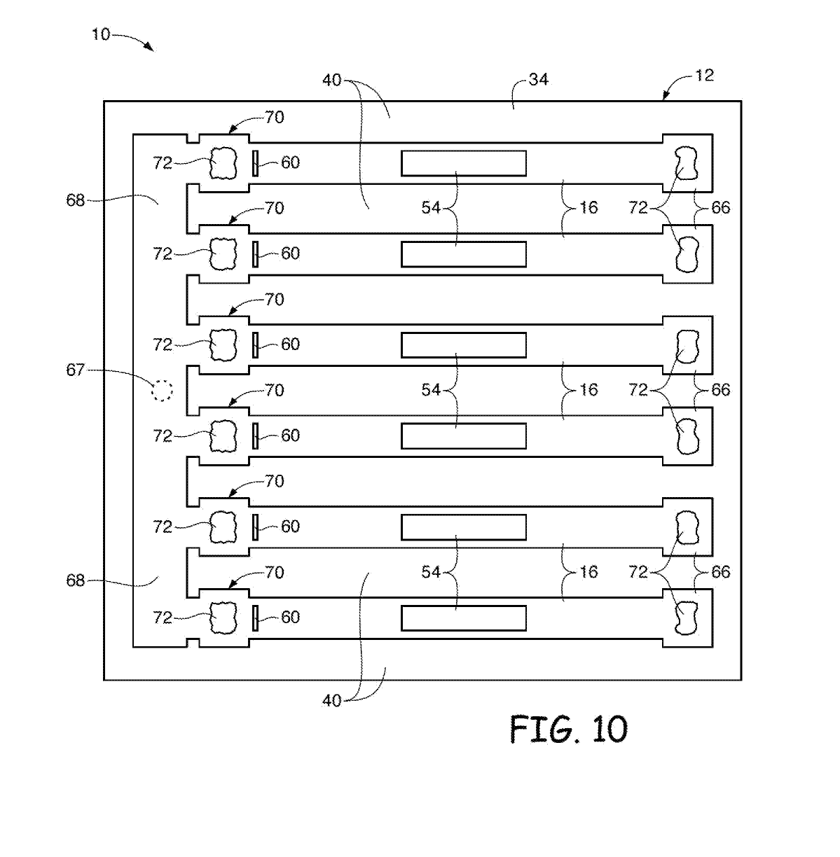

OFM 12 of OFM-SOC 11 of device 10 may include one or more channels 16 and one or more chambers 66 associated with each channel. FIG. 10 is an illustrative example of another embodiment of an OFM of the type that may be included in OFM-SOC 11 of FIG. 2 having multiple channels 16. In the example of FIG. 10, integrated circuit substrate (substrate 34) that has multiple channels 16. Channels 16 may, in general, be arranged on the surface of substrate 34 in a pattern with parallel channel segments (as shown in FIG. 10), in a pattern with perpendicular channel segments, in a pattern in which channels branch from one another at non-parallel and non-perpendicular angles, or other suitable channel patterns. The arrangement of FIG. 10 is merely illustrative. Sample reservoir 68 may have exit ports coupled to each of the channels. In the example of FIG. 10, there are six parallel channels 16, so there are six corresponding exit ports that couple sample reservoir 68 to channels 16. In systems with different numbers of channels (e.g., more than six channels or fewer than six channels), different corresponding numbers of exit ports may be formed in sample reservoir 68.

Fluid samples may be introduced into sample reservoir 68 through entrance port 67 (e.g., a hole in a cover such as hole 24 in cover layer 28 of FIG. 6). By introducing fluid into reservoir 68 through entrance port 67, a fluid sample may be distributed among the channels.

It may be desirable to introduce reactant into channels 16. For example, reactants may be used to make cells and other particles more visible within channels 16 (e.g., by staining the cells with dye, etc.). As shown in FIG. 10, reactant 72 may be supplied 10 to each channel 16 using a corresponding reactant chamber 70. There may be one or more different reactants in each reactant chamber 70.

OFM control circuitry such as OFM control circuitry 15 of FIG. 2 may be configured to operate gate structures 60 in order to control the amount of time that the sample spends in each reactant chamber 70. In some situations (e.g., when a reactant is slow-acting or when a longer reactant exposure time is desired), it may be desirable to hold the sample in a particular reactant chamber for a relatively long period of time. In other situations (e.g., when a reactant is fast acting or when a shorter reactant exposure time is desired), it may be desirable to hold the sample in a reactant chamber for a relatively short period of time. Using gate structures 60 of FIG. 10, some portions of a sample may be exposed to reactant 72 for longer than others portions of the sample. Different reactants may also be placed in different respective chambers 70.

Consider, as an example, a situation in which a particular type of cell is to be imaged following staining of the cell with a dye. The appearance of the stained cell may be different depending on how long the cell is exposed to the reactant. It may therefore be desirable to expose some portions of the sample to the reactant for short periods of time, while exposing other portions of the same sample to the reactant for longer periods of time. The cell may also respond differently to different concentrations of the reactant and different types of reactants. Using reservoir 68, a sample may be distributed to each of the reactant chambers 70 in OFM 12. Reactant chambers 70 may hold one or more types of reactant 72 in one or more different concentrations. Gate structures 60 may be used to hold the sample in different reactant chambers for different amounts of time (i.e., different sample hold times).

Once the sample has been held in a reactant chamber for a sufficiently long period of time, the gate structure that is associated with that reactant chamber may be opened to release the sample into an adjoining channel. Upon release, the sample in each channel will flow past the imager 54 (or imagers) in that channel. Camera control circuitry such as camera control circuitry 13 of FIG. 2 may be used to operate imagers 54 in gathering image data for the sample. The image data may be processed using camera control circuitry 13 to form images of the sample. The images that are formed may be displayed for a user on a display, may be stored in memory such as memory 14 of FIG. 1 or further processed or analyzed using processing circuitry 21 of FIG. 2. Because each imager 54 can gather image data from a sample that has been exposed to reactant in a different way (e.g., a different reactant type, different exposure time, different reactant concentration, etc.), each imager 54 can gather a different type of image data. During image processing operations using camera control circuitry 13 and processing circuitry 21, the image data may be processed to form images of cells and other particles in the sample.

As shown in FIG. 10, after a portion of the sample passes by each imager 54, that portion of the sample may flow into a corresponding FDC chamber 66. FDC chambers 66 may be spent sample reservoirs or may contain components for evaluating the sample. For example, chambers 66 may include components that are controlled by camera control circuitry 13 or FDC control circuitry 17 of FIG. 2 and that are been configured to serve as light sensors, light sources for illuminating the sample (e.g., for fluorescence measurements), heaters for heating the samples, additional reactant, etc.

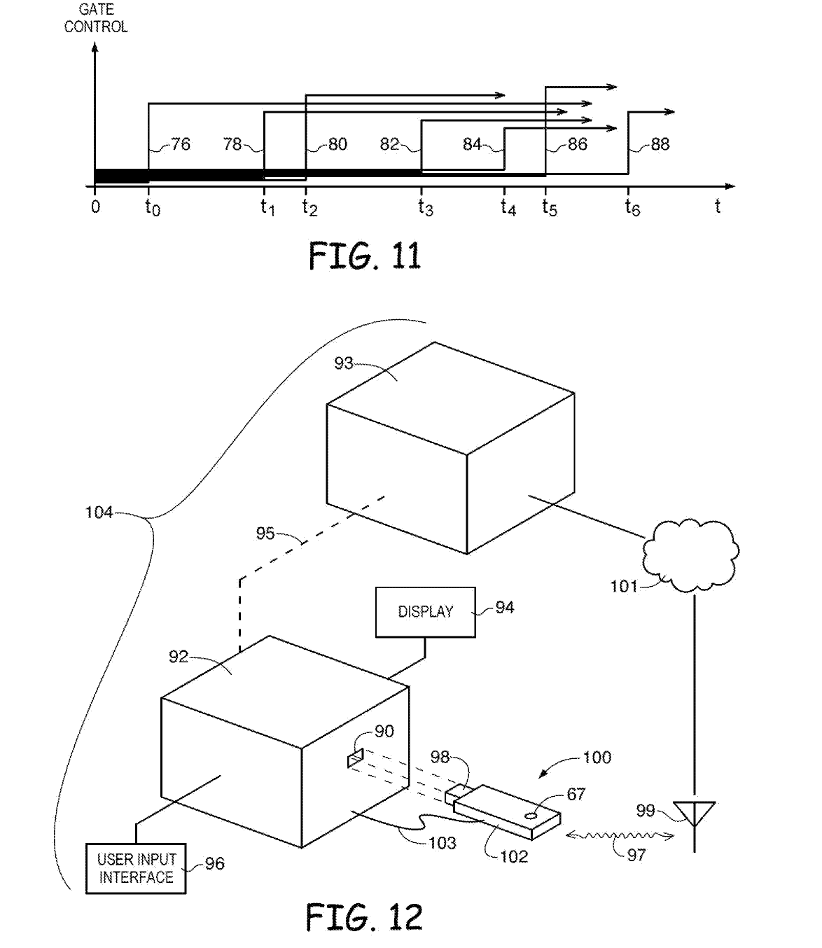

FIG. 11 is a graph showing how the control signals (i.e., signals generated using control circuitry 15 of FIG. 2) that are applied to each gate structure 60 in FIG. 10 may potentially be different. Each trace in the example of FIG. 11 corresponds to an illustrative control signal for a different respective one of the six gate structures 60 in FIG. 10. In this example, the status of the gate structures is controlled by the state of the control signal generated by OFM control circuitry 15. When the control signal for a given gate structure is deasserted (e.g., when the control signal is taken low), the gate structure is held in its closed state. When the control signal for a given gate structure is asserted (e.g., when the control signal is taken high using OFM control circuitry 15), the gate structure is placed in its open state. As shown in FIG. 11, at time t0, a first of the gate structures 60 (i.e., the uppermost gate structure 60 in FIG. 10) may be opened, whereas the remaining gate structures 60 remain closed. At time t1, a second of the gate structures 60 is opened by asserting control signal 78. The four remaining gate structures are likewise moved from their closed to open states at times t2, t3, t4, t5, and t6, respectively, as illustrated by control signals 80, 82, 84, 86, and 88. Using this type of arrangement, the portion of the fluid sample that is contained in the first reactant chamber (i.e., the sample in the uppermost reactant chamber in the example of 10 FIG. 10) is exposed to a first reactant in a first concentration for a first period of time (i.e., time t0, assuming that the fluid is placed in the reactant chambers at time t=0). The portion of the fluid sample that is placed in the other reactant chambers is exposed to reactant for different exposure times (i.e., sample hold times t1, t2, t3, t4, t5, and t6). Each reactant chamber potentially has a different type of reactant and a different reactant concentration. The use of potentially different respective hold times for the sample in each reactant chamber allows the hold times for holding the sample in the reactant chambers to be individualized to the type and concentration of reactant in each reactant chamber and other factors.

FIG. 12 is a perspective view showing how an electronic device 10 may be configured to communicate with data analysis equipment 104. Data analysis equipment 104 may be based on one or more computers or other computing equipment. Equipment 104 may, for example, include computing equipment such as computing equipment 92. An associated display such as display 94 may be used in presenting visual information to a user such as images of cells and other samples 25 acquired using device 10. User input interface 96 may be used to gather input from a user and to supply output for a user. For example, user input interface 96 may contain user input devices such as keyboards, keypads, mice, trackballs, track pads, etc. User input interface 96 may also include equipment for supplying output such as speakers for providing audio output, status indicator lights for providing visible output, etc.

Equipment 104 may include a data port such as data port 90. Data port 90 may be, for example, a Universal Serial Bus (USB) port. As shown in FIG. 1, device 10 may have an output port such as connector 98 (e.g., a USB connector) that is configured to mate with the connector in port 90. Connector 98 may be mounted in a housing 102 of device 10. Device 10 may include a fluid sample entrance port such as port 66. Port 66 may be aligned with port 66 of FIG. 2 or 10, so that samples that are placed in port 66 of device 10 flow into sample reservoir 68 of microscope 12 within housing 102. After a sample has been introduced into device 10 through port 67, camera control circuitry 13 on integrated circuit die 34 (FIG. 1) may be used to gather image data for forming one or more sample images.

After sample processing is complete, the user may insert device 10 into port 90, so that the data from device 10 may be passed to equipment 104 using general purpose processing circuitry 21 (FIG. 2) and further analyzed (e.g., to produce images of the sample from raw image data, to produce enhanced images, etc.).

Alternatively, device 10 may be connected to computing equipment 92 via a wired connection such as wired connection 103. Computing equipment 92 may be a portable electronic device (e.g., a mobile phone, a personal digital assistant, laptop computer, or other computing equipment). Computing equipment 92 may be used to process data from device 10. Computing equipment 92 may be used to transmit data from device 10 to computing and data processing equipment 93 along communications path 95. Communications path 95 may be a wired or wireless connection. Communications path 95 may be used to directly transfer data from device 10 to computing and data analysis equipment 93 using wireless communications circuitry formed on a common integrated circuit die with an OFM in device 10 such as wireless communications circuitry 19 of FIG. 2. Alternatively, communications path 95 may be used to transfer data from device 10 to computing and data analysis equipment 93 over a wired network. Computing and data processing equipment 93 may be a remote mainframe computer, may be a cloud computing network (i.e. a network of computers on which software can be run from computing equipment 92) or other computing equipment.

Wireless communications circuitry 19 in device 10 may be configured to transfer data over wireless communication path 97 to antenna 99. Antenna 99 may relay data communicated wirelessly from device 10 to a network 101 and to computing and data processing equipment 93. Equipment such as device 10 having an OFM-SOC such as OFM-SOC 11 (see, e.g., FIG. 2) may be produced inexpensively in volume and may be disposed of after a single use (as an example).

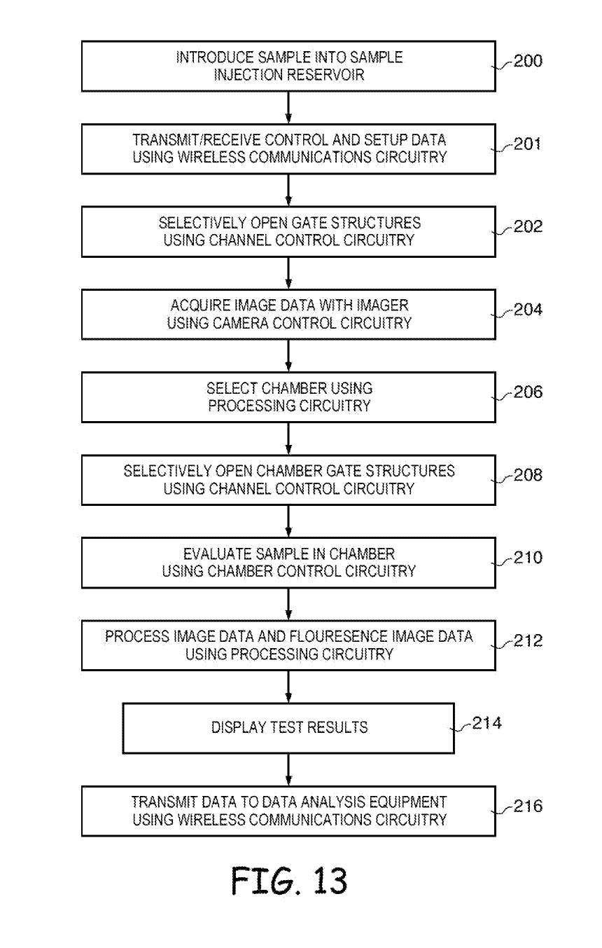

Illustrative steps involved in using an electronic device having an optofluidic microscope system-on-chip to gather and analyze data on a sample are shown in FIG. 13.

At step 200, a user of the device may place a sample in sample reservoir 68 (FIG. 3) through sample entrance port 67 (FIGS. 3 and 10). Once the sample flows into reservoir 68 and, if desired, associated reactant chambers 70, the sample will interact with the reactant.

At step 201, wireless communications circuitry 19 (FIG. 2) may be used to exchange (i.e., transmit and receive) data with a host system such as data analysis equipment 104 of FIG. 12. Data exchanged with data analysis equipment 104 may in clued control data for controlling OFM 12, setup data for configuring OFM 12 for testing or other data. If desired, wireless communications circuitry 19 may be used to exchange data with data analysis equipment 104 before introducing a sample into sample reservoir 68 as described in connection with step 200.

Different reactant chambers may require different amounts of sample hold time. Accordingly, OFM control circuitry 15 (FIG. 2) may selectively activate gate structures 60 during the operations of step 202. OFM control circuitry 15 may, for example, open gate structures 60 in different channels at different times, as described in connection with the gate control signals of FIG. 4. This causes the sample fluid from each reactant chamber to flow over a corresponding imager after being held for a different respective sample hold time.

At step 204, as the sample fluid flows over imagers 54, camera control circuitry 13 (FIG. 2) may operate imagers 54 to acquire image data for the cells or other samples in the fluid.

At step 206, image processing operations may be performed by processing circuitry 21 (FIG. 2) of device 10. During image processing operations, processing circuitry 21 may extract information from processed image data in order to determine an appropriate FDC chamber 66 for further analysis of the sample.

At step 208, OFM control circuitry 15 may selectively activate gate structures 60 associated with FDCs for further analysis of the sample.

At step 210, FDC control circuitry 17 (FIG. 2) may be used to operate image pixels, heaters, electrodes, light sources or other components of fluorescence detection chambers 66 during analysis of the sample.

At step 212, image processing operations may be performed using processing circuitry 21 on fluorescence image data captured in FDCs 66. Fluorescence image data may be analyzed using processing circuitry 21 to determine a test result from the fluorescence image data. As an example, a sample containing viral cells may fluoresce differently than a sample without viral cells. Processing circuitry 21 may be configured to determine the presence (or lack thereof) of viral cells in the sample based on the fluorescence image data.

At step 214, if desired, processing circuitry 21 may be used to operate a display associated with input-output devices 18 (FIG. 1) to display a test result (e.g., positive or negative viral test results) to a user of device 10.

Test results, image data, fluorescence image data or other data may be stored in memory 14 of device 10.

At step 216, wireless communications circuitry formed on integrated circuit die 34 (FIG. 2) may be used to transmit some or a portion of image data, fluorescence image data, test results (e.g., spectral analysis results, cell counting results, etc.) or other data to computing and data analysis equipment such as computing and data analysis equipment 93 of FIG. 12.

Various embodiments have been described illustrating an electronic device for imaging and evaluating samples of fluids containing cells and other materials. An integrated circuit may be provided with fluid channels and control circuitry. Sets of image sensor pixels from an image sensor array on the integrated circuit may form imagers in the fluid channels. Control circuitry on the integrated circuit may be configured to operate the image sensor pixels. The fluid channels and image sensor pixels may form a portion of an optofluidic microscope formed on the integrated circuit. The optofluidic microscope may include one or more reactant chambers, evaluation chambers or fluorescence detection chambers associated with each fluid channel. Control circuitry on the integrated circuit may be configured to operate gate structures within the channels to control fluid flow through the fluid channels. Control circuitry on the integrated circuit may be configured to operate gate structures adjacent to the evaluation chambers to control fluid flow from the fluid channels into the evaluation chambers.

A sample may be introduced into a channel for imaging by the imagers and for evaluation using other sample evaluation structures. The channels on the integrated circuit may have multiple branches. Flow control structures such as electrodes and gate structures such as microelectromechanical systems (MEMS) gate structures may be used to route fluid through various branches in the channel. For example, flow control structures may be used to route a sample to one or more different chambers for evaluation. Chambers in the channel may include reactant for reacting with the sample, a light source for providing illumination for the sample, a heater for heating the sample, and image sensor pixels. Chamber control circuitry on the integrated circuit may be configured to operate operable components such as the light source, the heater, and, if desired, the image sensor pixels. The image sensor pixels may be used in forming one or more light sensors in each chamber. Camera control circuitry on the integrated circuit may be configured to operate image pixels in the fluid channels for imaging of the samples. Camera control circuitry may be further configured to perform processing operations such as white balance and color correction of captured image data.

The optofluidic microscope SOC may include wireless communications circuitry on the integrated circuit die for wireless communicating data to remote computing equipment. The optofluidic microscope SOC may include general purpose processing circuitry on the integrated circuit die for image processing, temperature control or other operations of the OFM-SOC.

The foregoing is merely illustrative of the principles of this invention which can be practiced in other embodiments.

What is claimed is:

1. An integrated circuit, comprising:
image sensor pixels that form at least one imager;
a fluid channel on the integrated circuit that is configured to receive fluid, wherein the at least one imager is located in the channel;
at least one evaluation chamber having operable components; and
chamber control circuitry configured to operate the operable components.

2. The integrated circuit defined in claim 1 further comprising:
camera control circuitry configured to operate the image sensor pixels, wherein the at least one evaluation chamber that contains reactant, and wherein the evaluation chamber is configured to receive the fluid from the channel.

3. The integrated circuit defined in claim 2 wherein the operable components comprise:
a light source that illuminates the at least one evaluation chamber, wherein the chamber control circuitry is configured to operate the light source.

4. The integrated circuit defined in claim 2 wherein the operable components comprise:
a temperature control element configured to heat or cool a portion of the integrated circuit, wherein the processing circuitry is configured to operate the temperature control element.

5. The integrated circuit defined in claim 2 further comprising:
channel control circuitry; and
at least one gate structure in the fluid channel for controlling fluid flow in the fluid channel, wherein the channel control circuitry is configured to operate the at least one gate structure.

6. The integrated circuit defined in claim 5 wherein the at least one gate structure is adjacent to the at least one evaluation chamber and wherein the at least one gate structure is configured to control fluid flow into the evaluation chamber.

7. The integrated circuit defined in claim 6 further comprising:
at least one additional evaluation chamber coupled to the fluid channel that contains a second reactant; and
at least one additional gate structure adjacent to the at least one additional evaluation chamber, wherein the second reactant is different from the reactant, wherein the at least one additional gate structure is configured to control fluid flow into the at least one additional evaluation chamber, and wherein the channel control circuitry is configured to operate the at least one additional gate structure.

8. The integrated circuit defined in claim 1 further comprising wireless communications circuitry for transmitting data captured by the at least one imager.

9. The integrated circuit defined in claim 1 further comprising processing circuitry for processing data captured by the at least one imager.

10. An electronic device comprising:
an optofluidic microscope system-on-chip having an imager and control circuitry formed on a common integrated circuit substrate; and
memory configured to store data captured by the optofluidic microscope system-on-chip.

11. The electronic device defined in claim 10 further comprising:
a display, wherein the optofluidic microscope system-on-chip is configured to perform analysis of a sample, and wherein the display is configured to display a result of the analysis of the sample.

12. The electronic device defined in claim 11 wherein the optofluidic microscope system-on-chip comprises:
a fluid channel formed on the common integrated circuit substrate.

13. The electronic device defined in claim 12 wherein the optofluidic microscope system-on-chip further comprises:
wireless communications circuitry formed on the common integrated circuit substrate, wherein the control circuitry is configured to operate the imager, wherein the imager is configured to capture image data of the sample, and wherein the wireless communications circuitry is configured to transmit and receive data to and from a host system respectively.

14. The electronic device defined in claim 13 wherein the optofluidic microscope system-on-chip further comprises:
processing circuitry formed on the common integrated circuit substrate, wherein the processing circuitry is configured to process data associated with the analysis of the sample.

15. The electronic device defined in claim 14 wherein the optofluidic microscope system-on-chip further comprises:
a fluorescence detection chamber coupled to the fluid channel; and
fluorescence detection chamber control circuitry formed on the common integrated circuit substrate that is configured to operate components of the fluorescence detection chamber.

16. The electronic device defined in claim 15 wherein the optofluidic microscope system-on-chip further comprises:
at least one fluid control component for controlling fluid flow in the fluid channel; and
optofluidic microscope control circuitry formed on the common integrated circuit substrate that is configured to operate the fluid control component.

17. A method for analyzing fluid samples with an integrated circuit that has control circuitry and a plurality of image sensor pixels organized to form imagers in fluid channels on the integrated circuit, wherein the fluid channels include gate structures interposed between the fluid channels and reactant chambers, comprising:
with the control circuitry, selectively opening the gate structures to allow fluid to flow from the reactant chambers over the imagers in the channels.

18. The method defined in claim 17 further comprising:
with the control circuitry, operating the imagers to capture images of the fluid samples.

19. The method defined in claim 18, wherein the integrated circuit has wireless communications circuitry, the method further comprising:
with the wireless communications circuitry, transmitting the images of the fluid samples to external computing equipment.

20. The method defined in claim 19, wherein the integrated circuit has processing circuitry, the method further comprising:
with the processing circuitry, processing the images of the fluid samples.
